(19) United States
(12) Patent Application Publication
(10) Pub. No.: US 2002/0039027 A1
(43) Pub. Date: Apr. 4, 2002

(54) Dynamically periodical detecting method and detector

(75) Inventor: Chung-Wen Hung, Taipei (TW)

Correspondence Address: LADAS & PARRY, 26 WEST 61ST STREET, NEW YORK, NY, 10023, US

(73) Assignee: INDUSTRIAL TECHNOLOGY RESEARCH INSTITUTE

(21) Appl. No.: 09/749,047

(22) Filed: Dec. 27, 2000

(30) Foreign Application Priority Data
Aug. 25, 2000 (TW) 089117428

(51) Int. Cl. G01R 29/26

(52) U.S. Cl. 324/613

(57) ABSTRACT

The present invention discloses a dynamic period detecting method and detector, which utilizes a zero-crossing detecting method to detect a rough estimated period and then uses a weighting-average filtering method to eliminate noises to obtain an accurate period P. Since the average number for generating weight in the weighting-average filtering method is dynamically adjusted according to the period variation, the detecting method can detect the period correctly and fast, and save a lot of storage space and computation time.

### BACKGROUND OF THE INVENTION

1. Field of the Invention

The present invention relates to a dynamically periodical detecting method and detector, and particularly to a dynamically periodical detecting method and detector applied in a power analyzer to fast trace and measure the period of an input signal.

2. Description of Related Art

In general, the technology for detecting the period of an input signal includes two methods. The first one is to directly process an analog signal to be measured, such as PLL (Phase Lock Loop), and the second one is to firstly convert an analog signal to be measured into a digital signal by an A/D converter and then measure the digital signal. One example of the second one is a zero-crossing method disclosed in an U.S. Pat. No. 5834930, titled “Device for sensing the period of a digitized signal including noise evaluation and averaging over a plurality of zero crossing.”

The signal to be measured could comprise noises and glitches, and a DC component and period of the signal could be continuously varying. Therefore, the result would be erroneous if only a zero-crossing estimating method is adopted. Furthermore, although the zero-crossing estimation is easy to achieve, due to the interference of noises, the error of the result is larger than other prior art methods and needs an average filter for filtering the glitches. The above “Real-Time-Signal Periodical Detector” has proposed a method of averagely filtering signals, but it needs many operations. In other words, a rough estimated period is detected by a zero-crossing digital method, and an average filter is used to eliminate noises. Since the average filter adopts a method of averagely shifting filtering signals to add the rough estimated periods for the past N times and then averages the sum to obtain a more accurate period. The average filter needs N memory cells, (N−1) adders and a divider, and thus it needs many not only elements, but also the operations are complex. Besides, although the average filter can eliminate noise interference and output jitters, the speed to react to a dynamic input variation is still slow.

Therefore, how to implement a technology which does not have noise interference, has a fast response and is easy to implement is an important issue.

### SUMMARY OF THE INVENTION

Accordingly, one object of the present invention is to propose a dynamic period detector and detecting method for fast and efficiently detecting the period of an input signal.

Another object of the present invention is to propose a dynamic period detector and detecting method for correct on in various application fields.

For achieving the above goals, the present invention discloses a dynamic period detecting method which uses a zero-crossing detecting method to detect a rough estimated period, and then eliminates noises by an averagely filtering method to achieve an accurate period P. The characteristic of the averagely filtering method is done by the following equation:

$$p = {p}_{old} + \frac{( {p}_{new} - {p}_{old} )}{N}$$

Wherein P_{old} is a previously exact period, P_{new} is a rough estimated period at this moment and N is the number of dynamic average.

The present invention discloses a dynamic period detector utilizing a zero-crossing detecting method to detect a rough estimated period and then eliminate noises by an average filter to obtain an accurate period. The characteristic of the present invention is that the average filter includes a subtracter for estimating a periodic offset between a rough estimated period at a moment and a previously accurate period; an average number generator for generating an average number by comparing absolute values of said estimated periodic offset to a default maximum periodic offset; and a weighting-average filter for generating a newly accurate period by adding said previously exact period and a weighted value obtained by dividing said estimated periodic offset by said estimated average number.

By the above construction, the dynamic period detecting method and detector can be implemented and detected correctly by a simple circuit. Besides, the present invention can detect a remarkable variation of period, and the response speed can be increased. In an embodiment, an adjusting unit is provided to maintain a high performance state for every circumstance.

### BRIEF DESCRIPTION OF THE DRAWINGS

The present invention will be described in conjunction with the appended drawings, in which:

FIG. 1 is a system block diagram of a dynamic period detector according to a first embodiment of the present invention; and

FIG. 2 is a system block diagram of a dynamic period detector according to a second embodiment of the present invention.

### PREFERRED EMBODIMENT OF THE PRESENT INVENTION

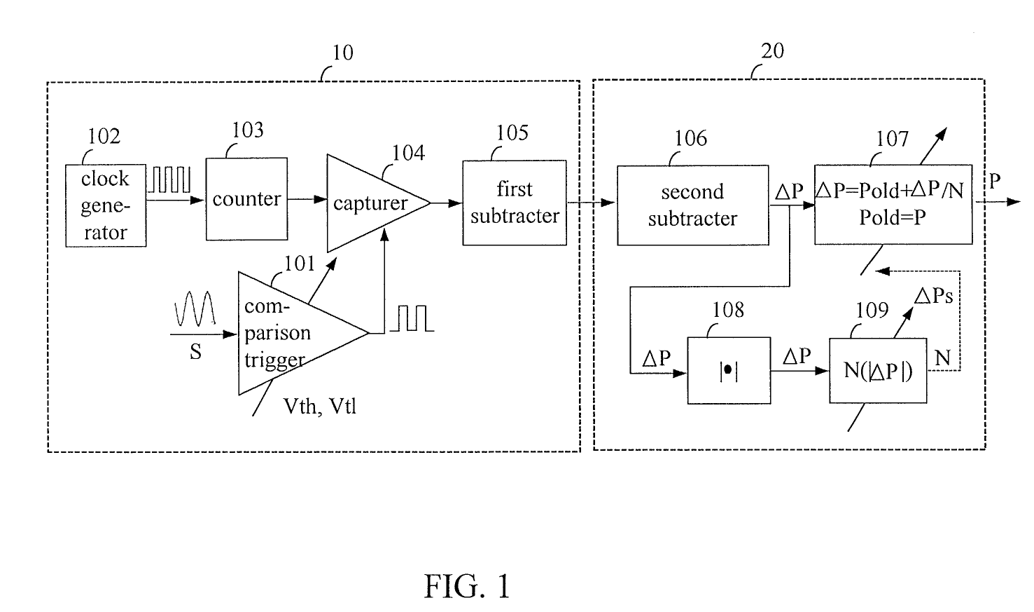

FIG. 1 is a system block diagram of a dynamic period detector according to a first embodiment of the present invention. The dynamic period detector 1 comprises a period detecting unit 10 utilizing a zero-crossing detecting method to detect a rough estimated period and averagely filtering unit 20 for eliminating noises and obtaining a stable signal period.

In other words, the period detecting unit 10 is used to initially detect a rough estimated period. The unit 10 comprises a comparison trigger 101, a clock generator 102, a counter 103, a capturer 104 and a subtracter 105. The averagely filtering unit 20 is used to determine if the rough estimated period involves a noise to be eliminated. The unit 20 comprises a second subtracter 106, a weighting-average filter 107, an absolute value generator 108 and an average number generator 109.

The comparison trigger 101 is used to determine if an input signal to be estimated is larger than a particular trigger level, and outputs the comparison result in a digital format. The clock generator 102 is used to generate clocks as a timing basis. The counter 103 is used to count the number of clocks outputted from the clock generator 102. The capturer 104 is used to capture the content of the counter 103 at the time of an output transition of the comparison trigger 101. The first subtracter 105 is used to store values captured by the capturer 104, and subtract the captured value from the previously captured value to generate a rough estimated period P_{new}. The second subtracter 106 is used to compute a periodic offset ΔP between the rough estimated period P_{new} and the previously accurate period P_{old}. The absolute value generator 108 is used to obtain the absolute value of the periodic offset ΔP. The average value generator 109 is used to generate an average number N transformed by a function N(·) which compares the absolute value of the periodic offset ΔP and a default maximum periodic offset ΔPs. The weighting-average filter 107 is used to generate a newly accurate period P by dividing the periodic offset ΔP by the average number N and adding the result to the previously accurate period P_{old}.

The comparison trigger 101 is constructed by a Schmidt trigger to prevent some noise interferences from causing zero-crossing triggers. The Schmidt trigger could be implemented by amplifiers or well-known TTL ICs. In this embodiment, a 7414 TTL IC can be used to implement. Besides, the trigger levels of the Schmidt trigger could be adjusted according to the characteristics of input estimated signals. As to other components, they could be implemented by well-known digital logic circuits or programming codes of a processor, or a mixture of the circuit and the codes. Thus, the advantages of these two implementations can be obtained. Since the constituent elements can be implemented by persons skilled in the art, the detailed description of the elements is omitted hereinafter. For example, the functions of the weighting-average filter 107 could be implemented by an adder, a multiplier and a memory.

By the above combination, when a signal S to be estimated is inputted into the comparison trigger 101, a logic level signal will be outputted. Besides, if the signal S passes a zero-crossing point, positive and negative levels will be alternated. By a positive edge (or negative edge) signal, the capturer 104 will be triggered, and the content of the counter 103 will be captured. The content represents the time at which the positive edge (or negative edge) of the signals S passes a zero point. Next, the first subtracter 105 determines an initially estimated signal period P_{new} by subtracting the newly captured time by the previously captured time.

Next, the rough estimated period is transmitted to the averagely filtering unit 20 to implement a weighting-average filtering method of the present invention. A second subtracter 106 and absolute value generator 108 are used to generate a period difference ΔP between the rough estimated period P_{new} and previously accurate period P_{old}. An average number generator 109 is used to compare the period difference ΔP with an adjustable default maximum period difference ΔPs to determining if the period difference ΔP is caused by a noise interference, floating of triggering levels or actually a period variation of the signals to be estimated. If the period difference is caused by the period variation of estimated signals, a smaller average coefficient N is outputted to the weighting-average filter 107. Otherwise, an average number N capable of filtering noises is outputted, and is determined by a function N(·) as follows:

N=N(|ΔP|)=M . . . if |ΔP|is not larger than ΔPs (Equation 1)

=O . . . if |ΔP|is larger than ΔPs

Wherein M is an average length of the weighting-average filter capable of filtering noises and varies different measuring systems and human experiences, and O is a value which approaches to one and is able to speed up a response, such as 2.

Finally, the weighting-average filter 107 generates an accurate period P according to the period difference ΔP, a previously accurate period P_{old} and a weighted coefficient N.

The averagely filtering method performed by the averagely filtering unit 20 can be mathematically expressed as follows:

$$p = {p}_{old} + \frac{( {p}_{new} - {p}_{old} )}{N}$$

Wherein P_{old} is a previously accurate period, P_{new} is a rough estimated period and N is the number of dynamic averages generated by the average number generator 109. Since the method of the present invention adopts a weighted calculation, it is called “weighting-average filtering method.”

By the computation of the above weighting-average filter 107 and average number generator 109, the dynamic period variation of the estimated signals, in which the frequency of the signals to be estimated is lowered from 60 Hz to 30 Hz or the period of the signals to be estimated is raised from 16.66 ms to 33.33 ms, could be fast traced and treated.

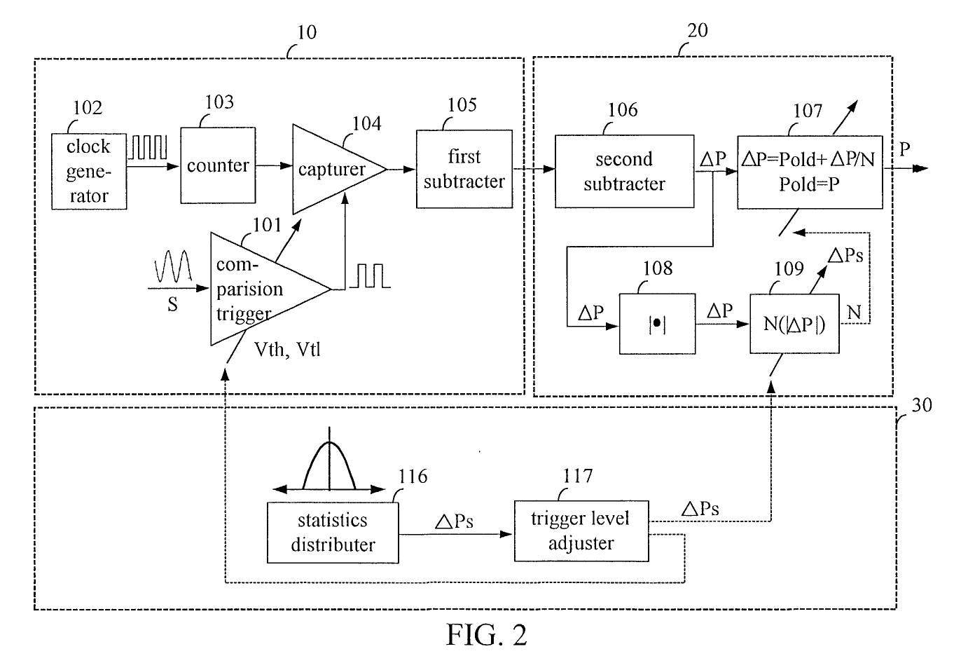

FIG. 2 is a system block diagram of a dynamic period detector 2 according to a second embodiment of the present invention. The difference between the dynamic period detector 2 and detector 1 resides in additionally provision of an adjusting unit 30 for adjusting the upper and lower thresholds of triggering levels of the period detecting unit 10 and the maximum periodic offset ΔPs of the averagely filtering unit 20. Since the period detecting unit 10 and averagely filtering unit 20 of the second embodiment is the same with that in the first embodiment, only the adjusting unit 30 is described in detail hereinafter.

The adjusting unit 30 can be implemented by hardware or software, and comprises a distribution estimator 116 and a level-triggered adjuster 117. The distribution estimator 116 is used to analyze the distribution of period and offset captured by the period detecting unit 10 and outputs a maximum offset ΔPs after adjustment for being used by the average number generator 109 when a known period signal source is detected by the period detecting unit 10 in an adjusting mode. The maximum periodic offset ΔPs will adjust the output of the function N(·). For example, the larger the maximum periodic offset ΔPs is, the larger the parameter M in equation 1 is. Besides, if the characteristic of the statistics distribution is not a monotonous function, the function N(·) in equation 1 will adopt a complex function to two or more powers.

The level-triggered adjuster 117 includes a function T(·), which outputs upper and lower threshold voltages Vth and Vtl for the comparison trigger 101 according to the maximum periodic offset ΔPs. In principle, the larger the distribution area is, the larger the difference between the upper and lower threshold triggering levels is. A typical function is listed as follows:

T(ΔPs)=α×(input range) (Equation 2)

Vth=+T(ΔPs)

Vtl=−T(ΔPs)

wherein α is a constant according to characteristics of a system, and is usually proportional to the parameter ΔPs to obtain the function of filtering noises.

By the adjusting unit 30, the period detecting unit 10 and averagely filtering unit 20 will perform in a best condition for every kind of applications and circumstances.

The above-described embodiments of the present invention are intended to be illustrated only. Numerous alternative embodiments may be devised by those skilled in the art without departing from the scope of the following claims.

What is claimed is:

1. A dynamic period detecting method, utilizing a zero-crossing detecting method to detect a rough estimated period and then eliminating noises by an averagely filtering method to obtain an accurate period P, characterized in that said averagely filtering method is conducted by
$$p = {p}_{old} + \frac{( {p}_{new} - {p}_{old} )}{N} ,$$
wherein P_{old} is a previously accurate period, P_{new} is a rough estimated period and N is the number of dynamic averages.

2. The method of claim 1, further comprising a step of generating the number N, and a step of generating a function N(·) of an absolute value of a period difference ΔP between said rough estimated period and said previously accurate period, wherein said function is determined by comparing said period difference ΔP and a default maximum periodic offset ΔPs, and the following is a typical form:
N−N(|ΔP|)=M . . . if |ΔP| is not larger than ΔPs=O . . . if |ΔP| is larger than ΔPs
wherein m is an average value capable of filtering noises, O is a value which approaches to one and is able speed up a response.

3. The method of claim 1, further comprising an adjusting step which includes:
detecting of a standard periodic signal;
accumulating distributions of rough estimated periods obtained from detected signals to generate a maximum periodic offset; and
generating upper and lower thresholds of zero-crossing trigger levels according to said maximum periodic offset.

4. The method of claim 3, wherein said upper and lower thresholds are generated by a function T(·) defined as follows:
T(ΔPs)=α×(input range)
Vth=+T(ΔPs)
Vtl=−T(ΔPs)
wherein α is a constant according to characteristics of a system.

5. A dynamic period detector, utilizing a zero-crossing detecting method to detect a rough estimated period and then eliminating noises by an average filter to obtain an accurate period, characterized in that said average filter includes:
a subtracter for determining a periodic offset between a rough estimated period and a previously accurate period;
an average number generator for generating an average number by comparing absolute values of said periodic offset and a default maximum periodic offset; and
a weighting-average filter for generating a newly accurate period by adding said previously accurate period and a weighted value obtained by dividing said periodic offset by said average number.

6. The dynamic period detector of claim 5, wherein said rough estimated period is obtained by a periodic detecting unit, and said periodic detecting unit comprises:
a comparison trigger for determining if an input estimated signal is larger than a particular high trigger level or less than a particular low trigger level, and then outputting the result in a digital format;
a clock generator for generating clock signals as a timing basis;
a counter for counting the number of clocks outputted from said clock generator;
a capturer for capturing the content of said counter at an output transition edge of said comparison trigger; and
a subtracter for generating said rough estimated period by subtracting the newly output value of said capturer from a previous output value of said capturer.

7. The dynamic period detector of claim 6, further comprising an adjusting unit which includes:
a distribution estimator for generating a maximum periodic offset by comparing a maximum periodic signal with estimated periodic values obtained from said subtracter when an adjusting mode is executed; and
a trigger level adjuster for generating upper and lower thresholds to trigger said comparison trigger according to said maximum periodic offset generated by said distribution estimator.

8. The dynamic period detector of claim 6, wherein said comparison trigger is constructed by a Schmidt trigger in which two triggering levels can be adjusted.

9. The dynamic period detector of claim 5, wherein said average number generator executes a typical function N(·) as follows:
N=N(|ΔP|)=M . . . if |ΔP| is not larger than ΔPs=O . . . if |ΔP| is larger than ΔPs
wherein ΔP is a period difference between the rough estimated period and previously accurate period, ΔPs is a default maximum periodic offset, M is an average value capable of filtering noises, and O is a value which approaches one and is able to speed up a response.
